(19) United States
(12) Patent Application Publication
(10) Pub. No.: US 2006/0115949 A1
(43) Pub. Date: Jun. 1, 2006

(54) Semiconductor fabrication process including source/drain recessing and filling

(75) Inventors: Da Zhang, Austin, TX (US); Mohamad M. Jahanbani, Austin, TX (US); Bich-Yen Nguyen, Austin, TX (US); Ross E. Noble, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freescale Semiconductor, Inc.

(21) Appl. No.: 11/000,717

(22) Filed: Dec. 1, 2004

(51) Int. Cl. H01L 21/336; H01L 21/44

(52) U.S. Cl. 438/300; 438/301; 438/607

(57) ABSTRACT

A semiconductor fabrication process includes forming a gate dielectric overlying a silicon substrate and forming a gate electrode overlying the gate dielectric. Source/drain recesses are then formed in the substrate on either side of the gate electrode using an NH₄OH-based wet etch. A silicon-bearing semiconductor compound is then formed epitaxially to fill the source/drain recesses and thereby create source/drain structures. Exposed dielectric on the substrate upper surface may be removed using an HF dip prior to forming the source/drain recesses. Preferably, the NH₄OH solution has an NH₄OH concentration of less than approximately 0.5% and is maintained a temperature in the range of approximately 20 to 35° C. The silicon-bearing epitaxial compound may be silicon germanium for PMOS transistor or silicon carbide for NMOS transistors. A silicon dry etch process may be performed prior to the NH₄OH wet etch to remove a surface portion of the source/drain regions.

### BACKGROUND

1. Field of the Invention

The invention is in the field of semiconductor fabrication processes and, more particularly, processes having high carrier mobility.

2. Related Art

In the field of semiconductor fabrication, source/drain recessing and filling with a strained layer has been proposed to improve transistor device characteristics and, specifically, the transistor drive current, by improving the mobility of the majority carrier in the transistor channel region. A source/drain recess is formed in the silicon substrate and filled with a different semiconductor material. The formation of the source/drain recess itself, however, has not been the focus of previous efforts and literature. The source/drain recess process must have a highly controllable etch rate and must be highly selective to the gate dielectric material such as silicon dioxide. Moreover, it would be highly desirable if the implemented source/drain recess process produced a smooth etched surface upon which a subsequent feature or structure could be formed by an epitaxial process.

### BRIEF DESCRIPTION OF THE DRAWINGS

The present invention is illustrated by way of example and not limited by the accompanying figures, in which like references indicate similar elements, and in which:

FIG. 1 is a partial cross-sectional view of a semiconductor wafer at a selected stage in an integrated circuit fabrication process, in which a transistor gate dielectric and gate electrode have been formed overlying the wafer;

FIG. 2 depicts processing subsequent to FIG. 1 in which a recess is formed in source/drain regions of a transistor to be formed;

FIG. 3 depicts processing subsequent to FIG. 2 in which the recess has been filled with a source/drain material to form a transistor of the integrated circuit;

FIG. 4 depicts alternative processing subsequent to FIG. 1 in which a first recess is formed in source/drain regions of the wafer using a first etch method; and

FIG. 5 depicts processing subsequent to FIG. 4 in which a second recess is formed in source/drain regions of the wafer using a second etch method; and

FIG. 6 depicts processing subsequent to FIG. 5 in which the source/drain recess is filled with a source/drain material to form a transistor of the integrated circuit.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

Generally speaking, the invention contemplates a technique and sequence for forming source/drain structures in an MOS (metal-oxide-semiconductor) semiconductor fabrication process. Following formation of the gate dielectric and gate electrode, portions of the source/drain regions are removed with a wet etch process to produce source/drain voids or recesses. These recesses are then filled with a semiconductor material, such as silicon germanium or silicon carbide, that differs in lattice constant from the substrate material, which is preferably silicon. The wet portion of the source/drain recess etch may be prefaced by a short dry etch of the source/drain regions. The wet etch of the source/drain regions preferably includes a step in which the substrate is immersed in a NH₄OH solution at room temperature or slightly above. In this embodiment, the NH₄OH etch exhibits controllable etch rates for silicon with excellent selectivity to other materials, such as silicon dioxide or silicon nitride, which may be present during the source/drain recess etch. In addition, the NH₄OH etch produces smooth surfaces upon which subsequently formed structures may directly be formed epitaxially onto the exposed semiconductor substrate.

Turning now to the drawings, FIG. 1 is a partial cross sectional view of a partially completed integrated circuit 100 at an intermediate stage in a semiconductor fabrication process according to one embodiment of the present invention. As depicted in FIG. 1, integrated circuit 100 is formed on a semiconductor wafer 101 that provides mechanical support for the integrated circuit and a suitable material from which to build. Wafer 101 includes a substrate 102, which is typically a doped or undoped, single crystal silicon substrate. Wafer 101 may be a “bulk” wafer in which substrate 102 extends to the wafer backside (not shown). Alternatively, wafer 101 may be a silicon-on-insulator (SOI) wafer in which substrate 102 is formed overlying a buried oxide layer (BOX) (not shown) that overlies a semiconductor bulk (not shown). Isolation structures 104, located in substrate 102, provide electrical and physical isolation between adjacent transistors or devices. The depicted isolation structures 104 are shallow trench isolation structures, but it will be readily appreciated that alternative isolation structures such as the well known LOCOS isolation structures may also be used.

As shown in FIG. 1, integrated circuit 100 includes a gate dielectric 106 formed overlying substrate 102. Gate dielectric 106 may be a thermally formed silicon dioxide, a silicon oxynitride, silicon nitride, a metal oxide compound, such as HfO, another suitable high dielectric constant film the like or combinations of the above. An equivalent oxide thickness (EOT) of gate dielectric 106 is preferably in the range of 1 to 5 nm.

A gate electrode 108 has been formed overlying gate dielectric 106. Gate electrode 108 is preferably a heavily doped, polycrystalline silicon (polysilicon), a metal or metal alloy such as tungsten, titanium, tantalum, titanium nitride, tantalum silicon nitride, the like, or combinations of the above. Gate electrode 108 is formed by depositing a gate electrode film and patterning the deposited film using conventional photolithographic techniques. Gate electrode 108 defines boundaries of a channel region 105 underlying the gate electrode and boundaries of as yet to be formed source/drain regions displaced on either side of the channel region 105.

A capping layer 109 has been formed overlying gate electrode 108. Capping layer 109 may serve as an antireflective coating (ARC) during the photolithographic processing of gate electrode 108. Capping layer 109 also protects gate electrode 108 during subsequent processing. Capping layer 109 is preferably a material such as silicon nitride. Optionally, capping layer 109 is removed prior to the subsequently occurring source drain recessing stage.

Spacers 110 are formed on sidewalls of gate electrode 108. In conventional processing, gate electrode sidewall spacers are employed to provide a hard mask for a source/drain implant so that the source/drain regions are laterally displaced from the transistor channel region. In the present invention, spacers 110 define a boundary for a source/drain recess etch process described in the paragraphs below with respect to FIG. 2. Like capping layer 109, spacers 110 may be silicon nitride spacers. Spacers 110 may be formed by depositing a conformal silicon nitride film and thereafter performing an anisotropic silicon nitride etch. Depending upon the implementation, the spacer structure may have multiple layers consisting of different materials.

FIG. 1 depicts elements 112 formed in substrate 102 and self-aligned to gate electrode 108. These elements are referred to herein as extension implants 112. Extension implants 112 are preferably formed by implanting an n-type or p-type impurity into substrate 102 after formation of gate electrode 108. In the case where the depicted portion of substrate 102 is a p-doped region or p-doped well, extension implants 112 are preferably n-type regions doped with arsenic or phosphorous. For an embodiment in which the depicted portion of substrate 102 is n-type, extension implants 112 are p-doped regions having a p-type impurity such as boron. Self alignment of extension implants 112 to gate electrode 108 is achieved by implanting the extension implants after forming gate electrode 108 as is well known in the field of semiconductor fabrication. Other implants (not depicted), such as halo implants, may also be performed.

Referring now to FIG. 2, source/drain recesses 114 have been formed in substrate 102. In the embodiment depicted in FIG. 2, source/drain recesses 114 are formed using a wet etch process. Wafer 101 is first immersed in a dilute solution of HF and deionized wafer. In one embodiment, the HF:H₂O ratio of the solution is approximately 100:1 and the duration of the dip is approximately 60 seconds. After the HF treatment, wafer 101 is dipped in a dilute, approximately room temperature solution of NH₄OH and deionized water. In one specific implementation, the source/drain recess wet etch includes dipping wafer 101 in an aqueous solution of NH₄OH maintained a temperature in the range of approximately 20-35° C. and having an NH₄OH concentration of less than approximately 0.5%. More preferably, the NH₄OH concentration is approximately 0.1% and solution temperature is approximately 24° C. The queue time from the first HF treatment to the next NH₄OH solution treatment is short and is preferably within 10 minutes.

The NH₄OH solution etches silicon substrate 102 with a controllable etch rate that is highly selective to silicon oxide and other materials such as silicon nitride. The etch rate of the source/drain recess etch is a function of solution temperature and concentration. Under the described conditions, the silicon etch rate is in the range of approximately 1.5 to 10 nm/min and the selectivity with respect to silicon oxide is in the range of approximately 350 to 450. In addition, the described source/drain recess wet etch produces extremely smooth recess surfaces upon which subsequent structures may be formed directly (i.e., without intervening cleaning or other processing).

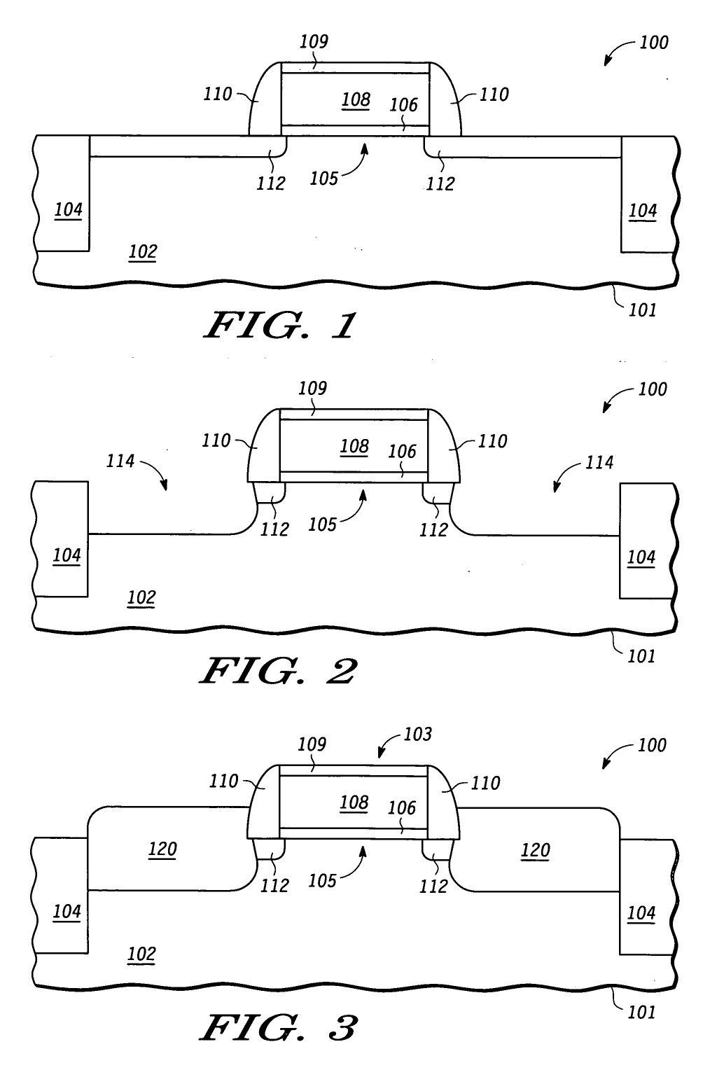

Referring now to FIG. 3, the source/drain recesses 114 formed in FIG. 2 are “filled” by forming source/drain structures 120. In the preferred embodiment, the source/drain recesses are filled by epitaxially growing a silicon-bearing semiconductor compound. In one embodiment suitable for use in fabricating PMOS devices, it is desirable to exert compressive stress on the channel region of substrate 102 underlying gate electrode 108 to improve the carrier mobility (i.e., hole mobility) in the channel. Such an effect is achieved by forming source/drain structures 120 with a semiconductor compound, such as silicon germanium, having a lattice constant that is greater than the lattice constant of substrate 102, which in one embodiment is silicon. Conversely, in an embodiment suitable for use in fabrication NMOS devices, carrier mobility is increased by exerting tensile stress on the transistor channel. Tensile stress is achieved by forming source/drain structures 120 with a semiconductor compound, such as silicon-carbon, having a lattice constant that is less than the lattice constant of substrate 102, which in one embodiment is silicon.

Thus, in one embodiment, source/drain structures 120 are epitaxial silicon germanium or silicon-carbon structures, depending upon the conductivity type (i.e., n-type or p-type) of the substrate 102. In a CMOS process, it will be appreciated that some portions of substrate 102 are p-type while other portions are n-type. Accordingly, in a CMOS implementation, the source/drain structures 120 for PMOS transistors may be silicon germanium while source/drain structures 120 formed for NMOS transistors may be silicon carbide.

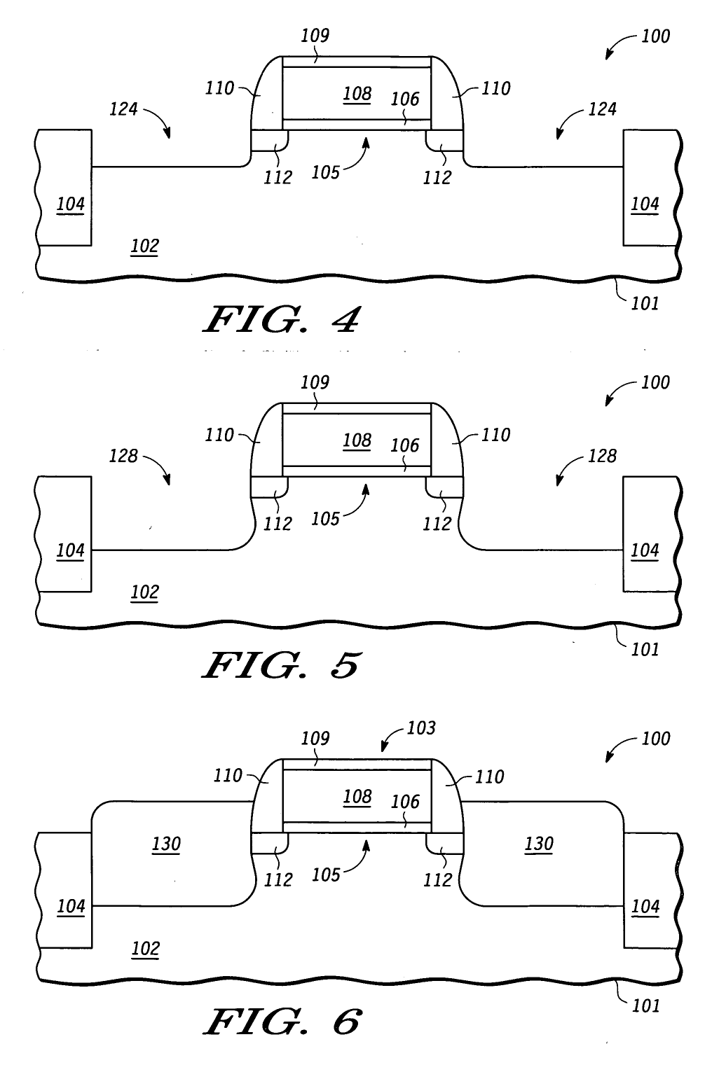

Referring now to FIG. 4 through FIG. 6, a second embodiment of the present invention is depicted. In this embodiment, formation of the source/drain recesses is initiated with a dry etch process. The use of an initial dry etch may be desirable to etch through unwanted or unintended films and/or impurities present at the surface of substrate 102. Native oxide films, for example, may form on substrate 102 if wafer 101 is exposed to an oxidizing ambient for any significant duration. In addition, other surface effects may create a substrate surface that is more readily etched with a dry etch process. Whereas wet etch processes are dependent upon chemical reactions, high energy particles typically associated with the plasma generated in dry etch processes create a mechanical-like etch component that is efficient in removing or etching through undesired surface states and films.

FIG. 4 through FIG. 6 illustrate a processing sequence that occurs after the processing depicted in FIG. 1 and in lieu of the processing depicted in FIG. 2 and FIG. 3. In FIG. 4, surface portions of substrate .102, identified by reference numeral 124, are removed with a plasma etch process as an initial step in the formation of source/drain recesses. Suitable plasma etch processes for a silicon substrate 102 are well known. Surface portions 124 of substrate 102 represent portions of substrate 102 in close proximity to the substrate upper surface. In a preferred embodiment, the surface portion 124 extends below the substrate upper surface to a depth in the range of approximately 10 to 50 nm.

In FIG. 5, source/drain recesses 128 are completed by dipping wafer 101 in an NH₄OH solution under the same conditions described above with respect to FIG. 2. Because the surface portions of substrate 102 are removed, the wet processing of FIG. 5 does not have to contend with unpredictable surface films. The combination of an initial dry etch followed by an NH₄OH dip therefore addresses the potential problem of etching through the surface films while retaining the controllable etch rate, high selectivity, and smooth finished surface characteristics of the wet etch.

In FIG. 6, the source/drain recesses 128 of FIG. 5 are filled by forming source/drain structures 130. Source/drain structures 130 are fabricated using a process that is substantially equivalent to the process described above with respect to the formation of source/drain structures 120. Thus, like source/drain structures 120, source/drain structures 130 are preferably composed of epitaxially deposited silicon-bearing semiconductor compounds such as silicon germanium (especially for PMOS regions) and silicon carbide (especially for NMOS regions).

Source/drain structures 130 (as well as 120) may be doped n-type or p-type depending on the type of transistor. Although doping of the source/drain structures may occur by implanting the dopant after epitaxial deposition of the structures, another embodiment achieves doping of the source/drain structures during the epitaxial growth of the structures.

In FIG. 3 and FIG. 6 the described processing results in the formation of a partially completed integrated circuit 100 including a transistor 103. Transistor 103 includes a gate dielectric 106 and a gate electrode 108 overlying a channel region 105 of a semiconductor substrate 102. Source drain/structures 120 (FIG. 3) and 130 (FIG. 6) are laterally displaced on either side of channel region 105 and gate electrode 108. The channel region 105 is composed of a first semiconductor material, which is preferably single crystal silicon. Source/drain structures 120 and 130 are composed of a second semiconductor material. The second semiconductor material is different than the fist semiconductor material and is preferably silicon germanium for PMOS regions of wafer 101 and silicon-carbon for NMOS regions of wafer 101.

In the foregoing specification, the invention has been described with reference to specific embodiments. However, one of ordinary skill in the art appreciates that various modifications and changes can be made without departing from the scope of the present invention as set forth in the claims below. For example, although the depicted processing sequence describes the recessing of transistor source/drain regions, the described wet etch process may be employed for other purposes requiring a controllable silicon etch. In addition, although the depicted processing illustrates the fabrication of a conventional transistor gate, other implementations may use a floating gate structure characteristic of nonvolatile memory devices. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor fabrication process, comprising:
forming a gate dielectric overlying of a silicon wafer substrate;
forming a gate electrode overlying the gate dielectric, wherein the gate electrode defines boundaries of first and second regions within the wafer substrate and wherein the gate dielectric and the gate electrode overlie the first region;
removing portions of the second region by immersing the wafer substrate in an NH₄OH solution; and
forming a silicon-comprising compound epitaxially to fill the removed portions of the second regions.

2. The method of claim 1, further comprising, after said forming of said gate electrode and prior to said removing portions of said second regions, removing any exposed oxide overlying the substrate using an HF dip.

3. The method of claim 2, wherein said removing portions of the second regions comprises using an NH₄OH solution having an NH₄OH concentration of less than approximately 0.5%.

4. The method of claim 3, wherein said removing portions of the source/drain regions comprises using an NH₄OH solution having a temperature maintained in the range of approximately 20 to 35° C.

5. The method of claim 4, wherein said removing portions of the source/drain regions comprises using a NH₄OH solution having an NH₄OH concentration of approximately 0.1% and a temperature of approximately 24° C.

6. The method of claim 1, wherein said forming of the silicon-bearing epitaxial compound comprises forming a silicon germanium compound epitaxially.

7. The method of claim 1, wherein said forming of the silicon-bearing epitaxial compound comprises forming silicon carbon compound epitaxially.

8. The method of claim 1, further comprising, prior to immersing the wafer substrate in the NH₄OH solution, performing a silicon dry etch process to remove a first portion of the source/drain regions wherein the immersing the wafer in the NH₄OH solution removes a second portion of the source/drain regions.

9. A semiconductor fabrication process, comprising:
forming a structure overlying a silicon substrate, wherein the structure exposes source/drain regions of the substrate; and
removing silicon from the source/drain regions using a dilute solution of NH₄OH;

10. The method of claim 9, wherein the forming of the structure comprises forming a gate dielectric comprised of a silicon oxide and a gate electrode overlying the substrate.

11. The method of claim 9, wherein removing the silicon from the source/drain regions comprises using a solution of NH₄OH having an NH₄OH concentration of less than approximately 0.5%.

12. The method of claim 9, wherein removing the silicon from the source/drain regions comprises using a solution of NH₄OH having an NH₄OH concentration of approximately 0.1%.

13. The method of claim 9, wherein removing the silicon from the source/drain regions comprises using a solution of NH₄OH maintained at a temperature in the range of approximately 20 to 35° C.

14. The method of claim 9, wherein removing the silicon from the source/drain regions comprises using a solution of NH₄OH maintained at a temperature in the range of approximately 24° C.

15. The method of claim 9, further comprising, depositing silicon germanium using an epitaxial process to fill the source/drain regions.

16. The method of claim 9, further comprising, depositing silicon carbide using an epitaxial process to fill the source/drain regions.

17. A method of fabricating an integrated circuit, comprising:
forming a gate dielectric overlying a silicon substrate and a gate electrode overlying the gate dielectric, wherein the gate electrode defines boundaries of source/drain regions in the substrate;
forming source/drain voids by removing portions of the source/drain regions with a wet etch; and
filling the source/drain voids with a compound selected from the group consisting of silicon germanium and silicon carbon.

18. The method of claim 17, wherein the forming of the source/drain voids comprises removing portions of the source/drain regions with a wet etch solution of NH₄OH and deionized water.

19. The method of claim 18, further comprising, prior to forming the source/drain voids, immersing the substrate in a dilute HF solution.

20. The method of claim 19, wherein the NH₄OH solution is maintained at a temperature in the range of approximately 20 to 35° C. and wherein an NH₄OH concentration of the NH₄OH solution is less than approximately 0.5%.

21. The method of claim 20, wherein the NH₄OH solution is maintained at a temperature of approximately 24° C. and a NH₄OH concentration of approximately 0.1%.
